(19) United States
(12) Patent Application Publication
(10) Pub. No.: US 2025/0308849 A1
(43) Pub. Date: Oct. 2, 2025

(54) FILM FORMING METHOD AND FILM FORMING APPARATUS

(71) Applicant: Tokyo Electron Limited, Minato-ku, Tokyo (JP)

(72) Inventors: Miyako KANEKO, Nirasaki City, Yamanashi (JP); Naoko SUZUKI, Nirasaki City, Yamanashi (JP)

(21) Appl. No.: 18/706,524

(22) PCT Filed: Oct. 24, 2022
(86) PCT No.: PCT/JP2022/039560

§ 371 Date: Oct. 22, 2024

(30) Foreign Application Priority Data
Nov. 4, 2021 (JP) 2021-180387

(51) Int. Cl. H01J 37/32; C23C 16/34; C23C 16/50; H01L 21/02

(52) U.S. Cl. CPC H01J 37/32155; C23C 16/345; C23C 16/50; H01J 37/3244; H01L 21/0217; H01L 21/02274; H01J 2237/332

(57) ABSTRACT

A film forming method includes placing a substrate on a stage provided inside a processing container; supplying a processing gas containing a silicon-containing gas and a nitrogen-containing gas into the processing container, and forming a silicon nitride film on the substrate by applying a first power with a first frequency higher than 300 MHz and a second power with a second frequency lower than the first frequency in a superimposition manner to an electrode facing the stage and plasmarizing the processing gas inside the processing container.

### TECHNICAL FIELD

The present disclosure relates to a film forming method and a film forming apparatus.

### BACKGROUND

In a manufacturing process of semiconductor devices, a silicon nitride film is formed on a semiconductor wafer (hereinafter also referred to as “wafer”), which is a substrate. The silicon nitride film is used as a hard mask or the like to cover a portion that is not removed by etching, for example, when patterning a formed film. Such a silicon nitride film is formed using, for example, a chemical vapor deposition (CVD) method by supplying a gas containing a film raw material and a gas for nitriding the film raw material to the wafer.

In film formation, there is a case where highly reactive active species, obtained by plasmarizing the above gases, are used.

For example, Patent Document 1 proposes a technique for applying power with two different frequencies to an upper electrode, in order to improve the film quality of an insulating film when depositing the insulating film on a semiconductor wafer in a parallel plate type plasma CVD apparatus. The two different frequencies are described as one being in the range of 10 to 100 MHz and the other being in the range of 200 to 500 kHz.

### PRIOR ART DOCUMENT

### Patent Document

Patent Document 1: Japanese Laid-Open Patent Publication No. 2002-367986

The present disclosure provides a technique for forming a silicon nitride film with good film quality.

### SUMMARY

The present disclosure provides a film forming method including: placing a substrate on a stage provided inside a processing container; supplying a processing gas containing a silicon-containing gas and a nitrogen-containing gas into the processing container, and forming a silicon nitride film on the substrate by applying a first power with a first frequency higher than 300 MHz and a second power with a second frequency lower than the first frequency in a superimposition manner to an electrode facing the stage and plasmarizing the processing gas inside the processing container.

According to the present disclosure, it is possible to form a silicon nitride film with good film quality.

### BRIEF DESCRIPTION OF DRAWINGS

FIG. 1 is a configuration example of a film forming apparatus according to the present disclosure.

FIG. 2 is a first characteristic graph illustrating measurement results of stress.

FIG. 3 is a first characteristic graph illustrating measurement results of film density.

FIG. 4 is a second characteristic graph illustrating measurement results of stress.

FIG. 5 is a second characteristic graph illustrating measurement results of film density.

FIG. 6 is a third characteristic graph illustrating measurement results of stress.

FIG. 7 is a third characteristic graph illustrating measurement results of film density.

FIG. 8 is a fourth characteristic graph illustrating measurement results of stress.

FIG. 9 is a fourth characteristic graph illustrating measurement results of film density.

FIG. 10 is a fifth characteristic graph illustrating measurement results of stress.

FIG. 11 is a fifth characteristic graph illustrating measurement results of film density.

FIG. 12 is a sixth characteristic graph illustrating measurement results of stress.

FIG. 13 is a sixth characteristic graph illustrating measurement results of film density.

FIG. 14 is a seventh characteristic graph illustrating measurement results of stress.

FIG. 15 is a seventh characteristic graph illustrating measurement results of film density.

FIG. 16 is an eighth characteristic graph illustrating measurement results of stress.

FIG. 17 is an eighth characteristic graph illustrating measurement results of film density.

FIG. 18 is a ninth characteristic graph illustrating measurement results of stress.

FIG. 19 is a ninth characteristic graph illustrating measurement results of film density.

FIG. 20 is a characteristic graph illustrating a relationship between stress and film density.

### DETAILED DESCRIPTION

### First Embodiment

### <Film Forming Apparatus>

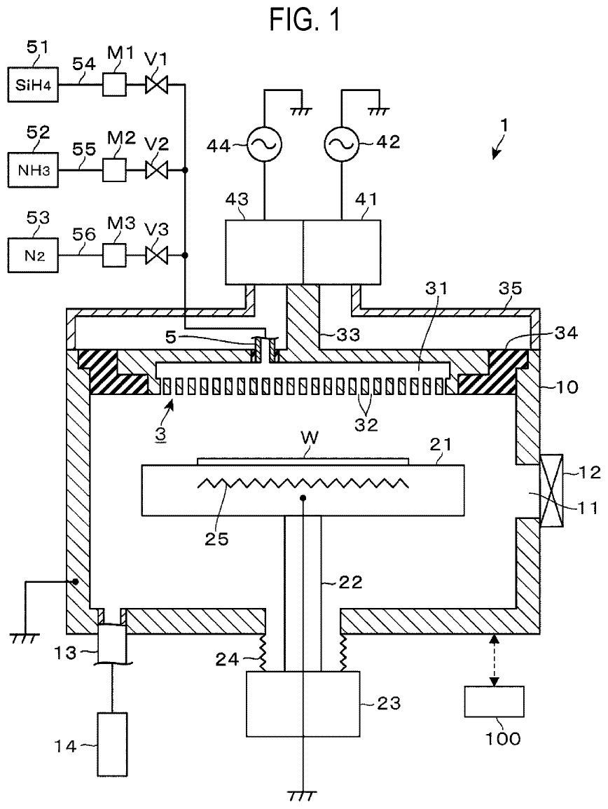

Referring to FIG. 1, a film forming apparatus 1 according to a first embodiment which forms a silicon nitride film (SiN film) on a wafer serving as a substrate will be described. FIG. 1 is a longitudinal sectional view of the film forming apparatus 1 in this example. The film forming apparatus 1 is configured as an apparatus that supplies a processing gas containing a silicon-containing gas and a nitrogen-containing gas to a surface of the wafer and forms a SiN film using a plasma CVD method.

Regarding a SiN film formed using plasma, it is sometimes necessary to form the film such that both tensile stress and film density have relatively high values. The tensile stress refers to stress that causes the wafer to bend like a bowl with a peripheral portion higher than a central portion when the wafer is placed on a horizontal surface. However, as will be described later in detail using experimental data, there is a trade-off relationship that when one of the tensile stress and the film density is increased, the other is decreased. A film forming method in the related art does not resolve matters described above. In addition, although it is conceivable to perform CVD by heating the wafer at a relatively high temperature with no plasma, there is a demand to form a SIN film at a relatively low temperature, in order to minimize thermal impacts on each film formed on the wafer, in conjunction with the miniaturization of semiconductor devices.

The film forming apparatus 1 of the present disclosure is configured to address the matters of the trade-off described above and form a good-quality SiN film with a high tensile stress and film density. An outline of the film forming apparatus 1 will be described. When forming capacitively coupled plasma inside a processing container, a first power with a first frequency higher than 300 MHz and a second power with a second frequency lower than the first frequency are supplied in a superimposition manner. In this way, a processing gas is plasmarized so that a SiN film is formed on the wafer. By performing the film formation by applying the powers in the superimposition manner and further adjusting the powers, the matter of the trade-off described above is resolved. Hereinafter, a configuration of each component of the film forming apparatus 1 will be described in detail.

The film forming apparatus 1 includes a grounded approximately cylindrical processing container 10 made of a metal. A loading/unloading port 11 is formed in a lateral side of the processing container 10 to load or unload the wafer between the processing container 10 and a vacuum transfer chamber (not illustrated). The loading/unloading port 11 is configured to be opened or closed by a gate valve 12.

Further, a vacuum exhauster 14, which includes, for example, a pressure regulation valve and a vacuum pump, is connected to a bottom of the processing container 10 via an exhaust path 13, and is configured to depressurize an interior of the processing container 10 to a preset vacuum pressure.

A stage 21 for holding the wafer W substantially horizontally is provided inside the processing container 10. The stage 21 in this example is grounded and constitutes a lower electrode to plasmarize the processing gas for a SiN film. The stage 21 is supported by a pillar 22 and is configured to be raised or lowered by a lifter 23 connected to a lower end of the pillar 22. The lifter 23 is positioned below the processing container 10, and a cover member 24 is provided between the bottom of the processing container 10 and the lifter 23 to keep the interior of the processing container 10 airtight.

A heater 25 is embedded in the stage 21 to heat the wafer W at a set temperature. In this example, a heating temperature of the wafer W is set, for example, to 320 degrees C. within the range of 250 degrees C. to 550 degrees C.

Further, lifting pins (not illustrated) are provided inside the processing container 10 to transfer the wafer W between the stage 21 and an external transfer mechanism (not illustrated). FIG. 1 illustrates an example where the lower electrode (the stage 21) is not connected to a bias radio-frequency power supply configured to supply bias radio-frequency power. In addition, the stage 21 may be configured to be connected to the bias radio-frequency power supply via a matcher.

Further, a flat disc-shaped shower head 3 is attached to a ceiling of the processing container 10 via an insulating member 34 to supply a film formation gas toward the wafer W. The shower head 3 constitutes an upper electrode facing the stage 21.

The shower head 3 has a diffusion space 31 formed therein to diffuse the processing gas. A plurality of discharge holes 32 are formed at a bottom of the diffusion space 31 in a distributed manner to discharge the processing gas toward the wafer W.

An electrode gap, which is a distance between an upper surface of the stage 21 and a lower surface of the shower head 3, is adjusted by raising or lowering the stage 21, and is set, for example, to 80 mm within the range of 60 mm to 120 mm.

One end of a feeding rod 33 is connected to an upper surface of the shower head 3. The other end of the feeding rod 33 is connected to a first radio-frequency power supply 42 via a first matcher 41 as well as a second radio-frequency power supply 44 via a second matcher 43. In the example illustrated in FIG. 1, the first and second matchers 41 and 43 are provided on an upper surface of a cover member 35 which covers an upper surface of the processing container 10. The first radio-frequency power supply 42 and the second radio-frequency power supply 44 constitute a power applicator.

The first radio-frequency power supply 42 and the second radio-frequency power supply 44 are configured to supply radio-frequency power with different frequencies for plasma generation to the shower head 3, respectively. The radio-frequency power supplied from the first radio-frequency power supply 42 is, for example, power with a frequency in an Ultra High Frequency (UHF) band. In this specification, the UHF band refers to a frequency range higher than 300 MHz and less than or equal to 3 GHz.

On the other hand, the second radio-frequency power supply 44 is configured to supply the radio-frequency power with a frequency lower than that supplied by the first radio-frequency power supply 42 as described above. This radio-frequency power is, for example, power with a frequency in a Very High Frequency (VHF) band. In addition, in this specification, the VHF band refers to a frequency range of 30 MHz to 300 MHz. Hereinafter, the frequency and power of the first radio-frequency power supply 42 will be referred to as a first frequency and a first power, respectively, and the frequency and power of the second radio-frequency power supply 44 will be referred to as a second frequency and a second power, respectively.

As described above, the film forming apparatus 1 of the present disclosure constitutes a parallel plate type plasma processing apparatus including the shower head 3 constituting the upper electrode and the stage 21 constituting the lower electrode. Further, by supplying the processing gas to the shower head 3 and applying the first power and the second power in a superimposition manner, two types of radio-frequency waves are radiated as a synthesized wave in a superimposition manner into the processing container, so that the processing gas is ionized to generate plasma.

As more specific examples of the first frequency and the second frequency, the first frequency is 360 MHz and the second frequency is 180 MHz. Thus, the first frequency is twice the second frequency. The reason for setting the first and second frequencies in this manner is that, when the first frequency is not an integer multiple of the second frequency, the synthesized wave, which is generated by superimposing two types of radio-frequency waves and is supplied into the processing container 10, may have irregularities, leading to significant variations in the in-plane film density and film thickness distribution of the wafer W.

In addition, from the viewpoint of minimizing variations in the in-plane processing of the wafer W, the first frequency may be 2n times the second frequency but is not limited to just twice (that is, n=1), and may also be four times the second frequency (that is, n=2). In other words, when the first frequency is 360 MHz as described above, the second frequency may be set to 90 MHz. However, if the second frequency is too low, sufficient film density may not be achieved, as illustrated in experimental data described later. Further, when the second frequency is set in a frequency range lower than the VHF band, ion energy in the plasma may be increased excessively. This results in deterioration in the film quality of the formed SiN film. Therefore, the first frequency may be set to 2n times the second frequency.

Therefore, as described above, it is desirable to set the first frequency to be twice the second frequency. In addition, in each experiment to be described, the second frequency was set to 180 MHz as described above to resolve the matter of the trade-off described above and achieve sufficient tensile stress and film density. Therefore, it is conceivable that a frequency slightly lower than 180 MHz, for example, a frequency of 100 MHz or higher may ensure sufficient film quality. In addition, a desirable relationship and range for the first power and the second power will be described later in conjunction with the description of experiments.

A gas supply path 5 is connected to the diffusion space 31 in the shower head 3 at an end portion of a downstream side of the gas supply path 5. An upstream side of the gas supply path 5 is connected to a source 51 of a silicon-containing gas such as a monosilane (SiH₄) gas, a source 52 of a nitrogen-containing gas such as an ammonia (NH₃) gas, and a source 53 of a dilution gas such as a nitrogen (N₂) gas via respective supply flow paths 54, 55 and 56. The supply flow paths 54, 55 and 56 are provided with flow rate regulators M1, M2 and M3 and valves V1, V2 and V3, respectively.

A mixture gas of the SiH₄ gas, the NH₃ gas and the N₂ gas is introduced into the diffusion space 31 in the shower head 3 via the gas supply path 5 and is then supplied as the processing gas into the processing container 10 via the discharge holes 32.

A processing gas supplier in this example includes the SiH₄ gas source 51, the NH₃ gas source 52, the supply flow paths 54 and 55, the gas supply path 5, and the shower head 3.

The film forming apparatus 1 having the above-described configuration includes a controller 100. The controller 100 is configured with a computer including a storage storing a program, a memory, and a CPU. The program incorporates instructions (steps) for executing the controller 100 to output control signals to each component of the film forming apparatus 1 and control the supply or cutoff of each gas as well as the supply of the first power and second power, thereby executing a film formation process of forming the SiN film. The program is stored in the storage of the computer, such as a compact disk, a hard disk, a magneto-optical (MO) disk, or a non-volatile memory, and is read from the storage and is installed on the controller 100.

### <Operation of Film Forming Process>

An operation of the film forming apparatus 1 having the configuration described above will be briefly described.

First, the gate valve 12 is opened, and the wafer W is loaded via the loading/unloading port 11 by a transfer mechanism provided inside the vacuum transfer chamber (not illustrated) and is placed on the stage 21 by the lifting pins (not illustrated) (in an operation of placing the substrate on the stage). Subsequently, the gate valve 12 is closed, and an interior of the processing container 10 is evacuated by the vacuum exhauster 14 so that the interior of the processing container 10 is adjusted to a preset pressure in the range of, for example, 3 Pa to 100 Pa. Further, the wafer W is heated to 320 degrees C. by the heater 25.

Subsequently, the supply of the processing gas is initiated (in an operation of supplying the processing gas into the processing container), and the first radio-frequency power supply 42 and the second radio-frequency power supply 44 start to supply the first power and the second power. By simultaneously supplying the first and second powers from the first and second radio-frequency power supplies 42 and 44, the first and second powers are applied to the shower head 3 in a superimposition manner. The expression “simultaneously supplying the first and second powers” means that the first and second powers are simultaneously supplied to the shower head 3.

Through the above-described operations, a capacitively coupled plasma is generated between the shower head 3 and the stage 21 inside the processing container 10 so that the supplied processing gas is plasmarized. In this way, the SiN film is formed on the surface of the wafer W by radicals or ions contained in the plasma (in a film formation operation of forming the silicon nitride film on the substrate).

Then, by continuing the film formation with the plasmarized processing gas for a preset period of time, the SiN film with a desired film thickness is formed. Subsequently, the supply of the first and second powers is terminated, and the supply of the processing gas is stopped. Thereafter, the wafer W is unloaded from the processing container 10 in a reverse order of the loading, and the apparatus waits for a subsequent wafer W to be loaded.

The SiN film formed using the film forming apparatus 1 configured as above is used as a hard mask, for example, in an etching process of performing a fine processing at a high aspect ratio. The SiN film needs to have a relatively high tensile stress and film density.

Subsequently, various experiments conducted to resolve the above-described trade-off relationship between the tensile stress and the film density and to find film formation conditions in which a good-quality SiN film with both high tensile stress and film density is obtained will be described along with data.

### <Evaluation Experiment at Single Frequency>

First, evaluation experiments were conducted by varying parameters, for a case where power, that is, radio-frequency power with a single frequency, is applied to the shower head 3 from a single radio-frequency power supply. The parameters to be evaluated were “electrode gap,” “power,” “internal pressure of the processing container (hereinafter sometimes referred to as “pressure”),” and “deposition rate.”

These evaluation experiments were conducted using the film forming apparatus 1 illustrated in FIG. 1 by applying the power to the shower head 3 from only the first radio-frequency power supply 42. Basic film formation conditions (reference conditions) before adjusting the parameters were as follows:
Frequency: 220 MHz;
Power: 2,700 W;
Electrode gap: 80 mm;
Pressure: 80 Pa (600 mTorr);
Deposition rate: 84 nm/min; and
Stage temperature: 320 degrees C.

### Evaluation Experiment 1: Electrode Gap

The operation of forming the SiN film was performed was performed by varying the electrode gap, and the stress (film stress) and film density of the obtained SiN film were measured. Parameters other than the electrode gap were set equal to those of the reference conditions. The stress was measured by acquiring a variation in bending (radius of curvature) by laser scanning at a wavelength of 680 nm, and the film density was measured by X-ray diffraction.

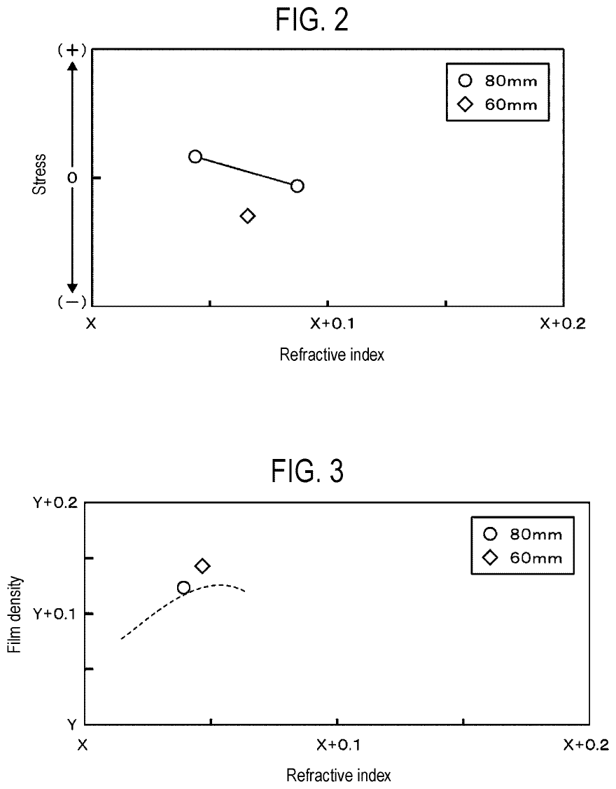

The measurement results of the stress and the film density are illustrated in FIGS. 2 and 3, respectively. In FIGS. 2 and 3, the horizontal axis represents the refractive index at a predetermined film thickness. The vertical axis in FIG. 2 represents the stress, where larger positive stress indicates greater tensile strength and the bending is increased in a bowl shape, while larger negative stress indicates greater compressive strength and the bending is increased in an inverted bowl shape. Thus, the tensile stress described above is stress with a positive value in the graph. In FIG. 3, the vertical axis represents the film density. Further, in the graphs of FIGS. 2 and 3, a predetermined refractive index and a predetermined film density are denoted as X and Y, respectively. Thus, these X and Y are positive numbers. In addition, even in subsequent characteristic diagrams of the measurement results of the stress and film density, the vertical and horizontal axes are the same as those in FIGS. 2 and 3. The refractive index at a predetermined film thickness is simply referred to as a refractive index. The refractive index X is, for example, in the range of X=1.95 to 2.05, and the film density Y is, for example, in the range of Y=2.70 to 2.85.

In FIGS. 2 and 3, data about the electrode gap of 60 mm were plotted with ⋄, and data about the electrode gap of 80 mm were plotted with ∘.

In FIG. 2, an approximation line, expressed by a linear function equation, is drawn from each plot corresponding to the electrode gap of 80 mm. As illustrated, the approximation line illustrates that the stress increases with a decrease in the refractive index. Comparing points on the approximation line with plots for the electrode gap of 60 mm at the same refractive index, the points on the approximation line indicate higher stress. In FIG. 3, an expectation line, which indicates a relationship between a film density and a refractive index expected from experimental rules based on plots for the electrode gap of 80 mm, is represented by a dashed line. As illustrated, this expectation line indicates that the film density increases with an increase in the refractive index until reaching a predetermined value. Comparing points on the expectation line with plots for the electrode gap of 60 mm at the same refractive index, the plots for the electrode gap of 60 mm indicate higher film density. From these results, it can be seen that, even if the electrode gap is adjusted, both the tensile stress and the film density are increased. Thus, the tensile stress and the film density are in a trade-off relationship.

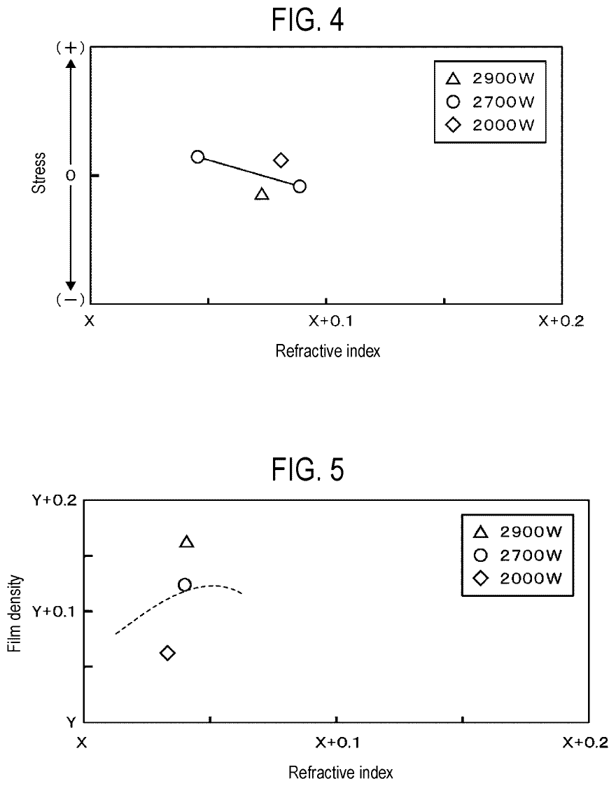

In addition, even in FIGS. 4 to 9 illustrating results of Evaluation Experiments 2 to 4 described later, approximation lines obtained from plots are represented by solid lines, and expectation lines are represented by dashed lines, similar to FIGS. 2 and 3. Hereinafter, comparative results for stress and film density at the same or approximately the same refractive index will be described based on both plots of data directly obtained from the experiments and points on the approximation lines or expectation lines.

### Evaluation Experiment 2: Power

The operation of forming the SiN film was performed was performed by varying the radio-frequency power applied to the shower head 3, and the obtained SiN film was evaluated in the same manner as in Evaluation Experiment 1. Parameters other than the power were set equal to those in the reference conditions.

Measurement results of the stress and the film density are illustrated in FIGS. 4 and 5, respectively. In these drawings, data about the power of 2,900 W were plotted with Δ, data about the power of 2,700 W were plotted with ∘, and data about the power of 2,000 W were plotted with ⋄.

As illustrated in FIG. 4, the stress decreases with an increase in the power. Thus, making the power lower is desirable. Moreover, it was found that the stress increases with a decrease in the refractive index under the same conditions. On the other hand, as illustrated in FIG. 5, the film density increases with an increase in the power. Thus, making the power higher is desirable.

As described above, it was found that even if the power is adjusted, the tensile stress and the film density are in a trade-off relationship

### Evaluation Experiment 3: Pressure

The operation of forming the SiN film was performed was performed by varying the internal pressure of the processing container 10, and the obtained SiN film was evaluated in the same manner as in Evaluation Experiment 1. Parameters other than the pressure were set equal to those in the reference conditions.

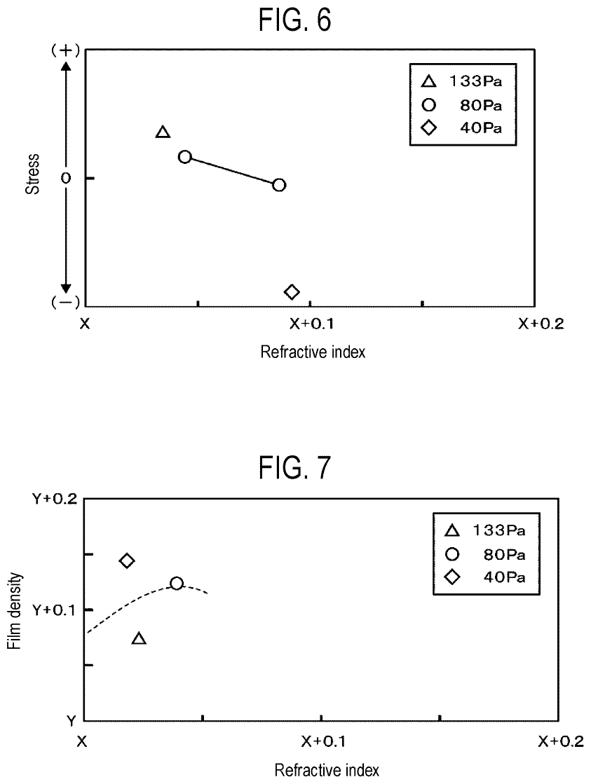

Measurement results of the stress and the film density are illustrated in FIGS. 6 and 7, respectively. In these drawings, data about the pressure of 133 Pa (1,000 mTorr) were plotted with Δ, data about the pressure of 80 Pa (600 mTorr) were plotted with ∘, and data about the pressure of 40 Pa (300 mTorr) were plotted with ⋄.

As illustrated in FIG. 6, the stress increases with an increase in the pressure. Thus, making the power higher is desirable. Moreover, it was found that the stress increases with a decrease in the refractive index under the same conditions. On the other hand, as illustrated in FIG. 7, the film density increases with a decrease in the pressure. Thus, making the pressure lower is desirable.

As described above, it was found that even if the pressure is adjusted, the tensile stress and the film density are in a trade-off relationship.

### Evaluation Experiment 4: Deposition Rate

The operation of forming the SiN film was performed by varying the deposition rate, and the obtained SiN film was evaluated in the same manner as in Evaluation Experiment 1. The deposition rate was adjusted by a flow rate of the processing gas, and parameters other than the deposition rate were set equal to those in the reference conditions.

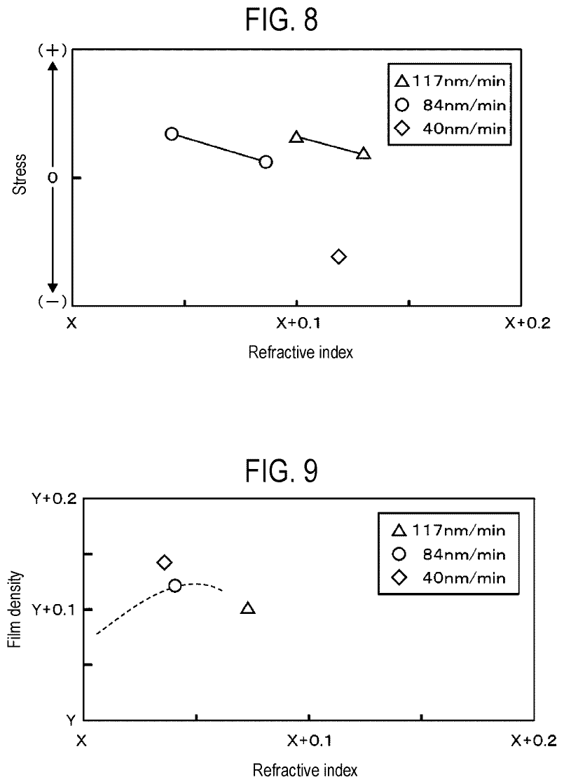

Measurement results of the stress and the film density are illustrated in FIGS. 8 and 9, respectively. In these drawings, data about the deposition rate of 117 nm/min were plotted with Δ, data about the deposition rate of 84 nm/min were plotted with ∘, and data about the deposition rate of 40 nm/min were plotted with ⋄.

As illustrated in FIG. 8, since the stress has a larger negative value at 40 nm/min, making the deposition rate higher is desirable. Further, it was found from values measured at the deposition rate of 84 nm/min and 117 nm/min that the stress increases with a decrease in the refractive index. On the other hand, as illustrated in FIG. 9, the film density increases with a decrease in the deposition rate, making the deposition rate lower is desirable.

As described above, it was found that even if the deposition rate is adjusted, that is, even if the flow rate of the processing gas is adjusted, the tensile stress and the film density are in a trade-off relationship.

It was found based on the above experimental data that, under the conditions that the ion energy in the plasma supplied to the wafer W is low with the increase in the electrode gap, the decrease in the radio-frequency power, the increase in the internal pressure of the pressure container, and the increase in the deposition rate, the stress of the SiN film is increased, the tensile stress is increased and the film density is decreased.

On the other hand, under the conditions that the ion energy is high with the decrease in the electrode gap, the increase in the radio-frequency power, the decrease in the internal pressure of the processing container, and the decrease in the deposition rate, the stress of the SiN film is decreased so that the compression progresses and the film density is increased.

The reason why the properties of the formed film vary due to different ion energies described above is presumed as follows. The dissociation of bonds in respective molecules of the SiH₄ gas and the NH₃ gas progresses sufficiently under the condition of high ion energy. By the dissociation of the bonds in the molecules of the SiH₄ gas, one or more H atoms from the molecules of the SiH₄ gas are desorbed, so that a relatively large amount of active species with Si atoms alone or with the Si atoms and H atoms bonded to each other, is contained in the plasma. Therefore, polymerization of the Si atoms on the wafer W is more likely to occur, so that the bonds between the Si atoms in the formed SiN film occur at a relative high rate. It is considered that the bonds have a relatively long bond length, which contributes to the progression of the compression.

Further, although the dissociation of bonds between N and H atoms in the NH₃ gas progresses sufficiently as described above, the presence of these bonds between N and H atoms in the film is considered to contribute to the generation of the tensile stress. For these reasons, the tensile stress tends to be relatively low when the film formation is performed under the condition of high ion energy. Further, comparing two bonded Si atoms with bonded Si and N atoms, the two bonded Si atoms are heavier. Under the condition of high ion energy as described above, the bonds between the Si atoms in the film occur at a relatively high rate so that the film density of the SiN film is relatively increased. Further, the dissociated H atoms are combined again to form H₂ and the formed H₂ is exhausted. As a result, the H atoms in the film is decreased. Therefore, it is considered that content ratios of Si—Si and Si—N are increased with the decrease in the H atoms in the film, which promotes the increase in the film density.

On the other hand, under the condition that the ion energy in the plasma supplied to the wafer W is low, the dissociation of bonds in respective molecules of the SiH₄ and NH₃ gases is suppressed. Therefore, unlike the film formation under the condition of high ion energy, the tensile stress is relatively high and the film density is relatively low.

In addition, in relation to the refractive index, the lower the refractive index, the larger the bonds between N and H atoms in the SiN film. As a result, the tensile stress is increased and the film density is decreased.

### Evaluation Experiment 5: Dependence on Frequency

Next, the operation of forming the SiN film was performed by varying the frequency of the applied radio-frequency power and the internal pressure of the processing container, and the obtained SiN film was evaluated in the same manner as in Evaluation Experiment 1. Parameters other than the frequency and the pressure were set equal to those in the reference conditions.

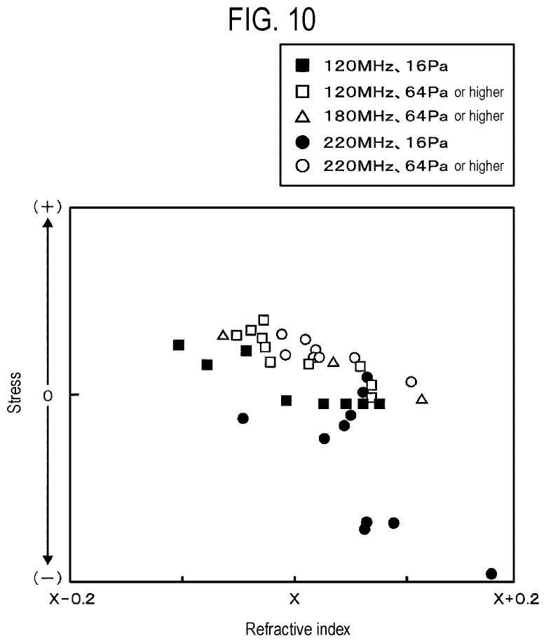

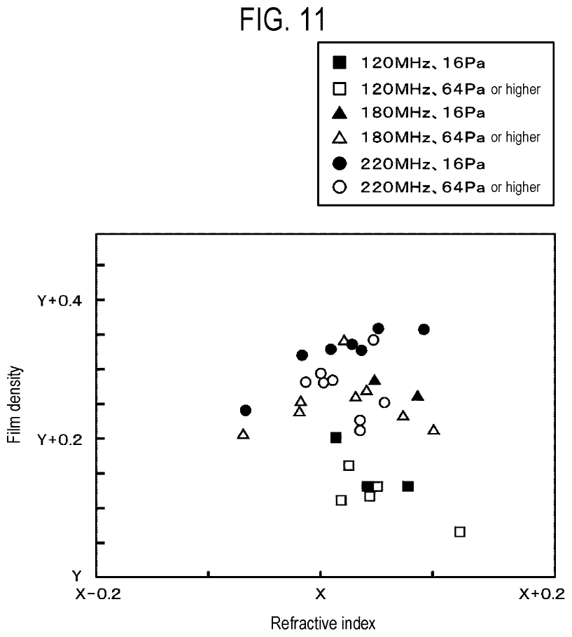

Measurement results of the stress and the film density are illustrated in FIGS. 10 and 11, respectively. In these drawings, data about the frequency (MHz) and data about the pressure (Pa (mTorr)) were plotted with the following symbols, respectively:
▪: 120 MHz, 16 Pa (120 mTorr)
□: 120 MHz, 64 Pa (480 mTorr) or higher
▴: 180 MHz, 16 Pa (120 mTorr)
Δ: 180 MHz, 64 Pa (480 mTorr) or higher
•: 220 MHz, 16 Pa (120 mTorr)
∘: 220 MHz, 64 Pa (480 mTorr) or higher

As illustrated in FIG. 10, a variation in measurement values of the stress is small even at different frequencies at the pressure of 64 Pa or higher. Thus, it can be said that the dependence on frequency is low. On the other hand, as illustrated in FIG. 11, measurement values of the film density tend to increase with an increase in the frequency. In other words, it was found from this experiment that, when the radio-frequency power in the range of 120 MHz to 220 MHz is applied, the higher the frequency, the higher the film density.

In addition, although not illustrated in the graph, a similar evaluation was also conducted for a case where radio-frequency power with a frequency higher than 220 MHz is applied. As a result, even when radio-frequency power with a frequency of 860 MHz in the UHF band or a microwave frequency is applied, the film density of the formed SiN film was approximately the same as that in the case where the radio-frequency power with a frequency of 220 MHz is applied. Considering the above experimental results and that manufacturing and operation costs tend to increase in an apparatus configured such that a frequency of radio-frequency power to be applied is high, it was confirmed that setting the frequency much higher than 220 MHz is not suitable as a measure for increasing the film density. In addition, even when a radio frequency of 860 MHz is applied to perform the film formation, it was found that the tensile stress and the film density are in a trade-off relationship as in Evaluation Experiments 1 to 4.

### Evaluation Experiment 6

In consideration of the results of Evaluation Experiment 5, a similar evaluation was conducted by varying the deposition rate for a case where radio-frequency power with a frequency of 220 MHz or higher in a UHF band is applied. Specifically, the film formation was performed by applying radio-frequency power of 2,700 W with a frequency of 360 MHz, and the obtained SiN film was evaluated in the same manner as in Evaluation Experiment 1. The deposition rate was set to 64 nm/min and a value (high deposition rate (DR): 76 nm/min) higher than 64 nm/min, and other parameters were set equal to those in the reference conditions. In addition, the “high deposition rate” in the following experimental data refers to a rate almost equivalent to that in this Evaluation Experiment 6.

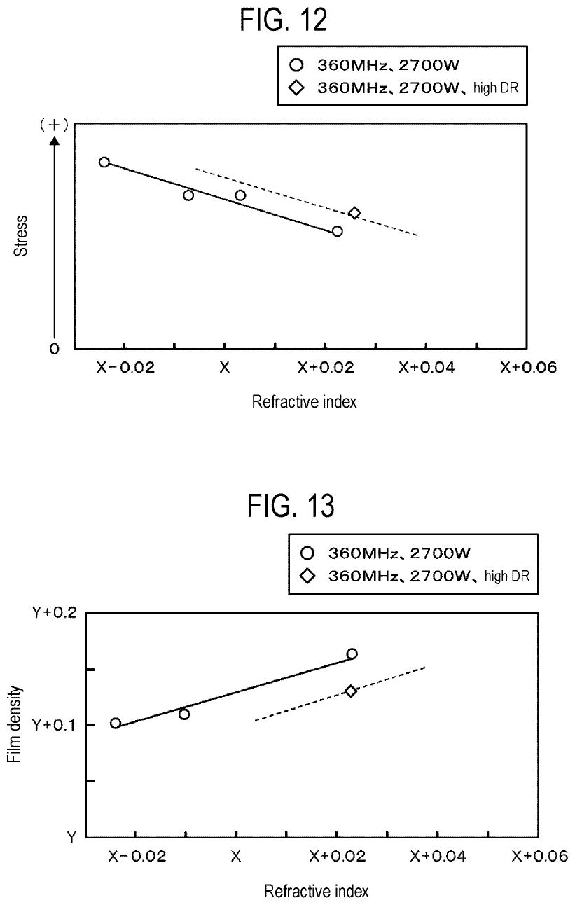

Measurement results of the stress and the film density are illustrated in FIGS. 12 and 13, respectively. In these drawings, data about the deposition rate under the reference conditions were plotted with ∘, and data about high DR were plotted with ⋄. In the graphs of FIGS. 12 and 13, approximation lines are drawn based on the data about the reference conditions. Each of the approximation lines follows the relationship between the stress and the refractive index or the relationship between the film density and the refractive index, which are obtained from experimental rules so far. To facilitate comparison, an expectation line illustrating the relationship between the stress and the refractive index and an expectation line illustrating the relationship between the film density and the refractive index, which are obtained from the data about the high DR, are represented by dashed lines in FIGS. 12 and 13, respectively, according to the experimental rules. The respective expectation lines, drawn based on the experimental rules, are in parallel with the approximation lines.

In each of the graphs in FIGS. 12 and 13, when comparing points on the approximation line with points on the expectation lines at the same refractive index, the high DR is higher than that in the reference conditions in terms of the stress, and is lower than that in the reference conditions in terms of the film density. In other words, it was confirmed that the tensile stress and the film density are still in a trade-off relationship.

### Summary of Evaluation Experiments

Based on the above experimental data obtained at a single frequency, the following was confirmed:

Even if the parameters such as “electrode gap,” “power,” “internal pressure of the processing container,” and “deposition rate” are adjusted, the trade-off relationship between the tensile stress and the film density in the SiN film was not resolved;

The stress has a low frequency dependence, while the film density tends to increase as the frequency increases, so that the stress and the film density remain approximately uncharged at the frequency of 220 MHz or higher; and

Even with the higher frequency of 360 MHz, the tensile stress and the film density in the SiN film are in the trade-off relationship.

### <Superimposition of First Frequency and Second Frequency: Example 1>

From the foregoing, it was determined that both the tensile stress and the film density in the SiN film are hard to be improved at a single frequency. Thus, evaluation was conducted focusing on the application of radio-frequency waves with different frequencies in a superimposition manner.

Specifically, the film formation was performed at a high deposition rate (79.2 nm/min) equivalent to that in Evaluation Experiment 6 using the single-frequency (76.3 nm/min) by applying the first power and the second power simultaneously from the first radio-frequency power supply 42 and the second radio-frequency power supply 44 (Example 1), and the obtained SiN film was evaluated in the same manner as in Evaluation Experiment 1.

The first frequency was set to a frequency in a UHF band, for example, 360 MHz, which is higher than 220 MHz at which the film density is determined to be good in the evaluation experiments. Further, the second frequency was set to half of the first frequency, that is, 180 MHz. The first power and the second power were as follows. The total power of the first and second powers is identical to that in each of Comparative Examples 1 and 2 as described later. Other parameters were set equal to those in the reference conditions.
First radio-frequency wave: first frequency of 360 MHz, first power of 1,350 W
Second radio-frequency wave: second frequency of 180 MHz, second power of 1,350 W

In Comparative Examples 1 and 2, similar evaluations were performed for a case where radio-frequency waves with a single frequency were applied. Conditions of each Comparative Example are as follows:
Comparative Example 1: frequency of 360 MHz, power of 2,700 W
Comparative Example 2: frequency of 360 MHz, power of 2,700 W, high deposition rate

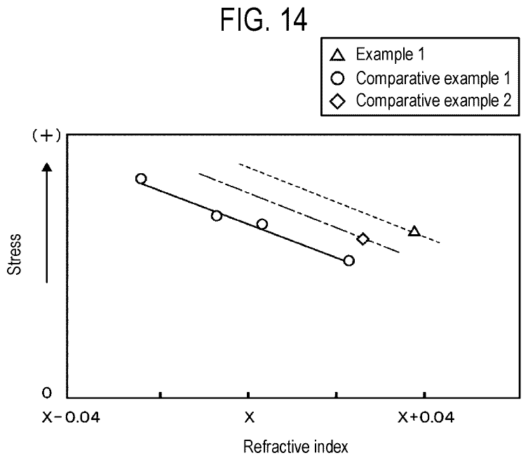

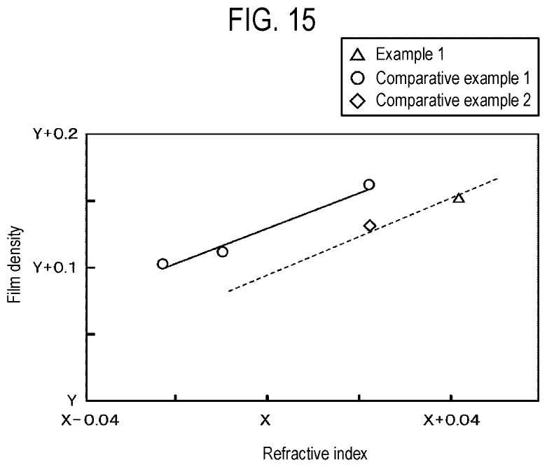

Measurement results of the stress and the film density are illustrated in FIGS. 14 and 15, respectively. Data in Example 1 was plotted with Δ, data in Comparative Example 1 was plotted with ∘, and data in Comparative Example 2 was plotted with ⋄. In these drawings, approximation lines, represented by solid lines, are drawn using a linear function equation based on multiple pieces of data in Comparative Example 1. Further, as in Evaluation Experiment 6, expectation lines are drawn in each graph of FIGS. 14 and 15. Dashed lines represent the expectation lines obtained from the data in Example 1, and one-dot dashed lines represent the expectation lines obtained from the data in Comparative Example 2. However, the expectation line in Comparative Example 2 is omitted in FIG. 15. The approximation line in Comparative Example 1 followed experimental rules. The expectation lines in Example 1 and Comparative Example 2 are drawn in parallel with the approximation lines in Comparative Example 1 based on experimental rules as in Evaluation Experiment 6.

As illustrated in FIG. 14, comparing stresses at the same refractive index, the stress in Example 1 was higher than those in both Comparative Examples 1 and 2. Comparing stresses in Example 1 and Comparative Example 2 under the condition of high deposition rate (high DR), the stress in Example 1 was higher than that in Comparative Example 2. Further, as illustrated in FIG. 15, comparing film densities at the same refractive index, the film densities in Example 1 and Comparative Example 2 were lower than that in Comparative Example 1. Comparing the film densities in Example 1 and Comparative Example 2 under the condition of high deposition rate, they were almost the same. A more specific description will be given. The plots of the data in Comparative Example 2 are located in contact with the expectation line in Example 1 illustrated in FIG. 15. As described above, the total powers supplied in Example 1 and Comparative Example 2 under the condition of high DR are the same. After such film formation conditions are set, when the application of power with a single frequency (Comparative Example 2) is changed to the application of power with two different frequencies (Example 1), the tensile stress was increased while the film density remains unchanged without a decrease. Accordingly, it was found that, by applying the first power with the first frequency and the second power with the second frequency lower than the first frequency in a superimposition manner as described in the section of <Film Forming Apparatus> above, the trade-off relationship between the tensile stress and the film density may be resolved.

### <Superimposition of First and Second Frequencies: Examples 2 to 4>

In the measurement results of the film density illustrated in FIG. 15, the film density in Example 1 was lower than that in Comparative Example 1. Thus, in Examples 2 to 4, evaluations were performed to find out conditions for improving the film density. Examples 2 to 4 are example in which the first and second powers are increased compared to Example 1. Conditions of these Examples are as follows. In addition, parameters other than the first and second powers were set equal to those in Example 1.

### Example 2

First frequency of 360 MHz, first power of 2,700 W
Second frequency of 180 MHz, second power of 1,400 W

### Example 3

First frequency of 360 MHz, first power of 2,700 W
Second frequency of 180 MHz, second power of 2,700 W

### Example 4

First frequency of 360 MHz, first power of 2,900 W
Second frequency of 180 MHz, second power of 2,900 W

As described above, by setting the first frequency to 360 MHz and the second frequency to 180 MHz, the first power is set to be greater than or equal to the second power. This is because, in the frequency range of 120 MHz to 220 MHz in Evaluation Experiment 5, the film density was increased as the frequency increases. In other words, in a case where radio-frequency waves with the first frequency of 360 MHz and radio-frequency waves with the second frequency of 180 MHz are applied independently of each other, when the radio-frequency waves with the first frequency of 360 MHz is applied, the film density increases. For the purpose of reliably obtaining the effects of radio-frequency waves with the first frequency, which ensures such an increase in the film density, the first power and the second power is set to be in the above-described relationship.

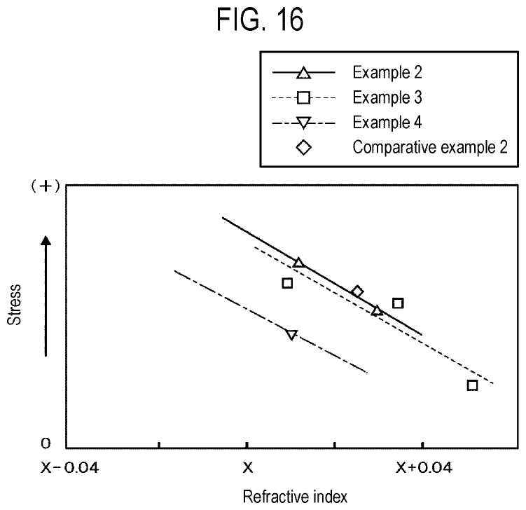

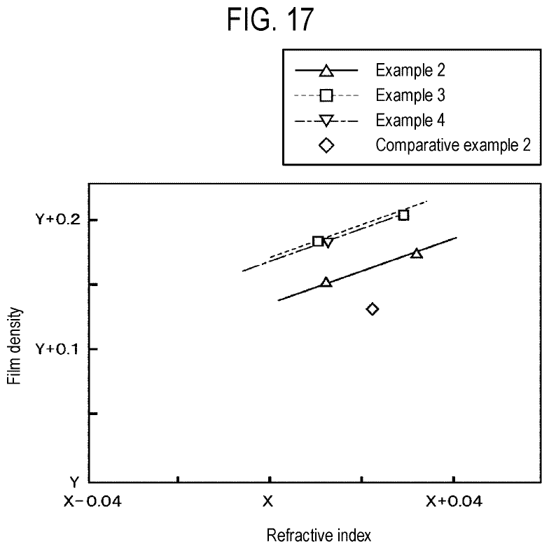

Measurement results of the stress and the film density are illustrated in FIGS. 16 and 17, respectively. In these drawings, data in Example 2 was plotted with Δ, data in Example 3 was plotted with □, and data in Example 4 was plotted with ∇. Further, data in Comparative Example 2 above was plotted with ⋄ in these drawings. In FIGS. 16 and 17, approximation lines based on the data in Example 2 are represented by solid lines, approximation lines based on the data in Example 3 are represented by dashed lines, and expectation lines based on the data in Example 4 are represented by one-dot dashed lines. Each approximation line was calculated using a linear function equation based on each data. Since one plot is illustrated in Example 4, an expectation line is drawn as being parallel to this approximation line.

From the results illustrated in FIG. 16, it was found that the stresses in Examples 2 and 3 were approximately equal to or slightly lower than that of Comparative Example 2, while the stress in Example 4 was lower than that in Comparative Example 2. Further, the stress in Example 3 was slightly higher than that in Example 2.

From the results illustrated in FIG. 17, it was confirmed that the film density in Examples 2 to 4 were higher than that in Comparative Example 2. Further, the film densities in Examples 2 and 3 were higher than that in Example 4, and the film density in Example 3 was slightly higher than that in Example 2.

As described above, in each of Examples 2 and 3 and Comparative Example 2 in which the high DR is set, radio-frequency waves of 360 MHz were supplied with power of 2,700 W. Under such film formation conditions, when the supply of the single frequency (Comparative Example 2) is changed to the supply of the frequency of 180 MHz at power of 1,400 W (Example 2) and at power of 2,700 W (Example 3) in a superimposition manner, the film density was increased while the tensile stress remains unchanged without a decrease. Although in Example 4, the tensile stress and the film density are in a trade-off relationship, such a trade-off relationship was resolved in Examples 2 and 3. Therefore, it is understood from these experimental results that, by appropriately establishing a relationship between the first power and the second power and applying the first power with the first frequency and the second power with the second frequency in a superimposition manner, it is possible to resolve the trade-off relationship. Further, it can be seen from Examples 2 and 3 that, as an example of the appropriate relationship, the second power may be set in the range of 1,400 W to 2,700 W when the first power is set to 2,700 W.

### Summary of Examples

Based on the experimental data in Examples 1 to 4 above, it was found that, by applying the first power with the first frequency in a UHF band and the second power with the second frequency in a VHF band in a superimposition manner, it is possible to resolve the matters of trade off described above. In other words, it was confirmed that the SiN film has a relatively high tensile stress and film density.

In addition, in order to obtain a relatively high film density, the first frequency may be a frequency in a band higher than the UHF band. However, as described in Evaluation Experiment 5, even if the frequency is increased to be higher than a certain magnitude, the film density hardly increases. Therefore, the first frequency may be set to be in the UHF band. Further, from the viewpoint of obtaining a relatively high film density and preventing a film quality from degrading due to the ion energy as described in the section of <Film Forming Apparatus>, the second frequency may be set to a relatively high value. In Examples 1 to 4 described above, the second frequency is set to be in the VHF band to resolve the trade-off relationship by setting the VHF-band frequency, but the second frequency is not limited thereto. For example, in a case where the first frequency is set to a relatively high frequency in a UHF band, the second frequency may be set to a frequency in the UHF band.

Further, as described in Examples 2 to 4, the first power is set to be equal to or greater than the second power (that is, the second power is less than or equal to the first power) to increase the film density. In these Examples, a ratio of the second power to the first power is set to be in a range of ½ to 1 to resolve the trade-off relationship. Thus, such a ratio relationship of the second power to the first power is desirable.

Further, in Example 4 where both the first and second powers are set to 2,900 W, the trade-off relationship between the first power and the second power could not be resolved. However, in Examples 1 to 3 where the first and second powers are set to 1,350 W, 1,400 W, and 2,700 W, the trade-off relationship between the first power and the second power was resolved. Therefore, the first and second powers may be set to values of 1,350 W or higher and less than 2,900 W, more particularly, to values of 1,350 W or higher and 2,700 W or lower. In addition, the second power may be set to be less than 2,700 W. This will be described with reference to subsequent experiments.

In the above, the expression “applying the first power and the second power to the shower head 3 in a superimposition manner” means that both the first and second powers are applied to the shower head 3. Therefore, this encompasses not only the case where the applications of the first and second powers from the first and second radio-frequency power supplies 42 and 44 are initiated in a simultaneous manner, but also a case where time periods during which the first power and the second power are applied overlap even if timings at which the applications are initiated are deviated. However, in a case where a difference in the timings at which the applications are initiated is increased, the film density of the SiN film, which is formed when neither the first power nor the second power is applied, may decrease, and a composition of the SiN film in a depth direction may vary. Therefore, the application of the first and second powers may be initiated in a simultaneous manner.

### Effects

According to the film forming apparatus 1 described above, the following effects are obtained. The processing gas is plasmarized by applying the first power with the first frequency higher than 300 MHz and the second power with the second frequency lower than the first frequency in a superimposition manner. This makes it possible to form a good-quality SiN film with well-balanced tensile stress and film density.

### Second Embodiment

Next, a second embodiment of the present disclosure will be described. When applying radio-frequency powers with different frequencies in a superimposition manner, there may be a case where the stress and film density of the SiN film need to have relatively high values. To do this, this embodiment provides adjusting parameters to further improve the tensile stress and film density of the SiN film.

A film forming apparatus of this embodiment is configured to supply a hydrogen gas (H₂ gas) unlike the film forming apparatus 1 of the first embodiment. In the film forming apparatus of the second embodiment, the H₂ gas is supplied together with the processing gas to the shower head 3, and the operation of forming the SiN film is performed using the same method as in the first embodiment.

At this time, parameters such as “internal pressure of the processing container,” “flow rate of the hydrogen gas,” “electrode gap,” and “second power,” are adjusted to improve the stress and film density of the SiN film.

The following description is based on experimental data. Film formation conditions before the adjustment of the parameters (Example 10) are as follows:
Internal pressure of the processing container: 80 Pa (600 mTorr);
Flow rate of SiH₄ gas: 85 sccm;
Flow rate of NH₃ gas: 132 sccm;
Flow rate of H₂ gas: 0 sccm;
Flow rate of Ar gas: 1,500 sccm;
Electrode gap: 80 mm;
First frequency: 360 MHz;
First power: 2,700 W;
Second frequency: 180 MHz; and
Second power: 2,700 W

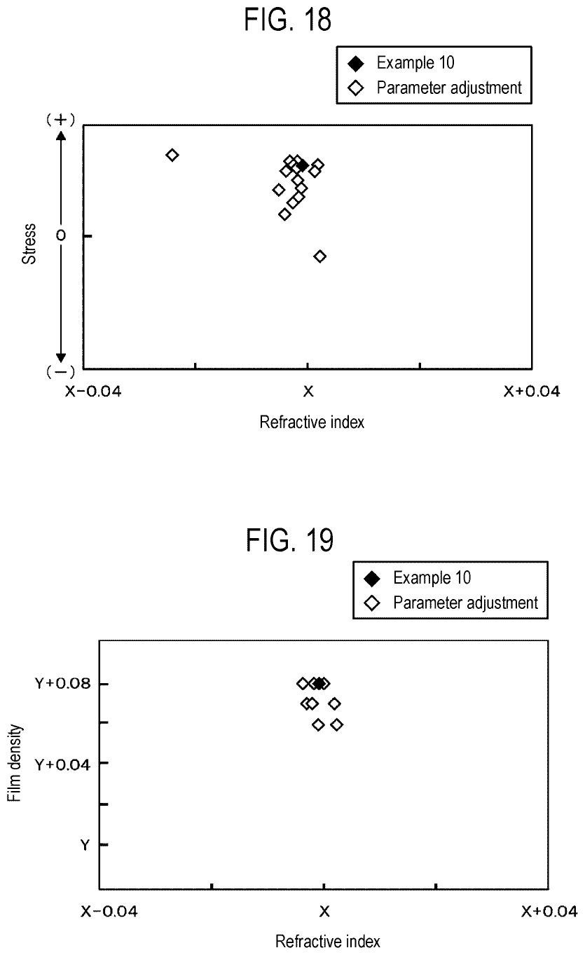

The stress and film density of the SiN film formed under the film formation conditions of Example 10 are illustrated in FIGS. 18 and 19, respectively. In these drawings, data was plotted with ♦.

Further, pieces of data in cases of adjusting parameters such as “pressure,” “flow rate of the hydrogen gas,” “electrode gap,” “ratio of N₂ gas to NH₃ gas in flow rate,” and “flow rate of Ar gas” among the film formation conditions of Example 10 one by one are plotted with ⋄ in FIGS. 18 and 19. These pieces of data are obtained when forming the SiN film by varying only one corresponding parameter among the conditions of Example 10.

As a result, it was found that there are favorable conditions for stress equivalent to that of Example 10 at a lower refractive index than that in Example 10, but values of the stress are less than that in Example 10 under many conditions. Further, it was found that the film density is equal to or less than that in Example 10. From the foregoing, it was found that, in a single parameter adjustment in which the parameters are adjusted one by one, the stress and film density are not improved as much.

Therefore, an attempt was made to simultaneously adjust four parameters such as “pressure,” “flow rate of the hydrogen gas,” “electrode gap,” and “second power.” Film formation conditions after such a parameter adjustment (Example 11) are as follows:
Internal pressure of the processing container: 86 Pa (650 mTorr);
Flow rate of SiH₄ gas: 85 sccm;
Flow rate of NH₃ gas: 129 sccm;
Flow rate of H₂ gas: 125 sccm;
Flow rate of Ar gas: 1,492 sccm;
Electrode gap: 70 mm;
First frequency: 360 MHz;
First power: 2,700 W;
Second frequency: 180 MHz; and
Second power: 2,500 W.

As described above, compared to Example 10, the conditions in Example 11 was set such that “pressure” is increased, “flow rate of the hydrogen gas” is decreased, “electrode gap” is decreased, and “second power” is decreased. In addition, although there are slight differences in “flow rate of NH₃ gas” and “flow rate of Ar gas” in Examples 10 and 11, these differences do not affect the stress and film density of the SiN film.

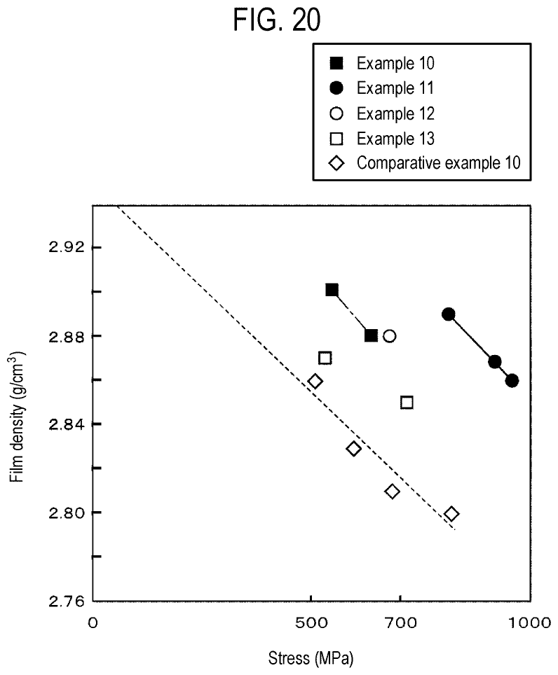

The stress and film density of the SiN film formed under the film formation conditions of Example 11 are illustrated respectively in FIG. 20, with data plotted with •. In FIG. 20, the vertical axis represents the film density, and the horizontal axis represents the tensile stress (denoted as stress).

Further, in the same drawing, data in Example 10 was plotted with ▪, data in Example 12 was plotted with ∘, data in Example 13 was plotted with □, and data in Comparative Example 10 was plotted with ⋄. Conditions used in Example 12, Example 13, and Comparative Example 10 are as follows:
Example 12: an example where only the parameter “flow rate of the hydrogen gas” is changed to 199 sccm compared to Example 10;
Example 13: an example where only the parameter “second power” is changed to 1,400 W compared to Example 10; and
Comparative Example 10: a comparative example where the application of the second power from the second radio-frequency power supply in Example 10 is stopped, and only a single frequency with a first frequency of 360 MHz and a first power of 2,700 W is applied

As a result, it was found that the film quality in Examples 10 and 13 is improved compared to that in Comparative Example 10, and measurement values of the stress and film density in Example 10 where the second power is increased from 1,400 W to 2,700 W are increased compared to those in Example 13.

Further, in Example 12 where only the parameter “flow rate of the hydrogen gas” is adjusted, the stress was 675 MPa and the film density was 2.88 g/cm³, which were further improved compared to those in Example 10. H atoms present in the SiN film are impurities. It is presumed that, when the hydrogen gas is added, hydrogen radicals and ions contained in plasma desorb the H atoms from the SiN film, thereby effectively influencing the improvement in the film quality.

Further, it was found that, in Example 11 where all four parameters in Example 10 are adjusted simultaneously, the stress and film density are significantly improved compared to those in Examples 10 and 12, so that the SiN film may be formed with a film density of 2.88 g/cm³ or higher and a stress of 700 MPa or higher, more specifically, a film density of 2.89 g/cm³ and a stress of 811 MPa.

In Example 11, the parameter “pressure,” was increased, the parameter “flow rate of the hydrogen gas” was decreased, the parameter “electrode gap” was decreased, and the parameter “second power” is decreased compared to those in Example 10. In Example 11, the parameter adjustment (relating to the pressure and the second power) in which the ion energy in plasma is decreased and the parameter adjustment (relating to the electrode gap) in which the ion energy in plasma is increased are combined.

As a result, it is presumed that, by the interaction of the effects of these parameters, the stress and film density may have relatively high values, and the film quality of the SiN film may be significantly improved.

### Effects of Second Embodiment

In Example 11, the parameter “pressure” was set to be greater than 80 Pa, the parameter “flow rate of the hydrogen gas” was set to be less than 199 sccm, the parameter “electrode gap” was set to be less than 80 mm, and the parameter “second power” was set to be less than 2,700 W. By setting the parameters in this way, it is possible to form a SiN film with good characteristics, especially in terms of stress and film density.

### OTHER EMBODIMENTS

The film forming apparatus 1 for forming a SiN film is not limited to the configuration illustrated in FIG. 1. Instead of providing the first radio-frequency power supply and the second radio-frequency power supply separately, a configuration may be employed in which powers with two different frequencies are supplied from a common radio-frequency power supply.

Further, the composition of the processing gas supplied into the processing container 10 to form the SiN film is not limited to the example described above. For example, the silicon-containing gas may include not only the SiH₄ gas, but also a disilane (Si₂H⁶) gas or a higher-order silane gas containing three or more silicon atoms in the molecule. Alternatively, an organic silane gas such as an aminosilane-based gas may be used as the processing gas.

In the above-described embodiments, the NH₃ gas has been described as a nitrogen-containing gas, but the N₂ gas used as a dilution gas may also be plasmarized to serve as a source of nitrogen to the SiN film. In other words, the N₂ gas functions as both a carrier gas and a nitrogen-containing gas. In addition to the N₂ gas and the NH₃ gas, trimethylamine and triethylamine may be used as the nitrogen-containing gas.

Further, in addition to the N₂ gas, an inert gas such as an argon (Ar) gas or a helium (He) gas may be used as a dilution gas. Moreover, the silicon nitride film formed by this technique is not limited to be used as a hard mask but may be used as a barrier film for preventing diffusion of wiring metals or as an interlayer insulating film.

The embodiments disclosed herein should be considered to be exemplary and not limitative in all respects. The above embodiments may be omitted, replaced or modified in various forms without departing from the scope of the appended claims and their gist.

### EXPLANATION OF REFERENCE NUMERALS

1: Film forming apparatus
10: Processing container
21: Stage
3: Shower head (electrode)
42: First radio-frequency power supply
44: Second radio-frequency power supply

1. A film forming method comprising:
placing a substrate on a stage provided inside a processing container;
supplying a processing gas containing a silicon-containing gas and a nitrogen-containing gas into the processing container; and
forming a silicon nitride film on the substrate by applying a first power with a first frequency higher than 300 MHz and a second power with a second frequency lower than the first frequency in a superimposition manner to an electrode facing the stage and plasmarizing the processing gas inside the processing container.

2. The film forming method of claim 1, wherein the second frequency is a frequency in a VHF band.

3. The film forming method of claim 2, wherein the second frequency is 100 MHz or higher.

4. The film forming method of claim 2, wherein the first frequency is a frequency that is 2n times the second frequency (where n is an integer).

5. The film forming method of claim 4, wherein the n is one.

6. The film forming method of claim 5, wherein the first frequency is 360 MHz, and the second frequency is 180 MHz.

7. The film forming method of claim 1, wherein the forming the silicon nitride film includes initiating the application of the first power and the second power to the electrode in a simultaneous manner to form the silicon nitride film.

8. The film forming method of claim 1, wherein the second power is less than or equal to the first power.

9. The film forming method of claim 8, wherein each of the first power and the second power is 1,350 W or higher and less than 2,900 W.

10. The film forming method of claim 1, wherein the second power is less than 2,700 W.

11. The film forming method of claim 1, wherein in the forming the silicon nitride film, an internal pressure of the processing container is greater than 80 Pa.

12. The film forming method of claim 1, wherein the processing gas contains a hydrogen gas.

13. The film forming method of claim 12, wherein in the forming the silicon nitride film, the hydrogen gas is supplied into the processing container at a flow rate less than 199 sccm.

14. The film forming method of claim 1, wherein in the forming the silicon nitride film, a distance between the electrode and the stage is less than 80 mm.

15. The film forming method of claim 1, wherein the processing gas contains a hydrogen gas, the second power is less than 2,700 W, an internal pressure of the processing container is greater than 80 Pa in the forming the silicon nitride film, the hydrogen gas is supplied into the processing container at a flow rate less than 199 sccm, and a distance between the electrode and the stage is less than 80 mm.

16. The film forming method of claim 1, wherein the forming the silicon nitride film forms the silicon nitride film with a film density of 2.88 g/cm³ or higher and a stress of 700 MPa or higher.

17. A film forming apparatus comprising:
a processing container including a stage provided therein to place a substrate thereon;
a processing gas supplier configured to supply a processing gas containing a silicon-containing gas and a nitrogen-containing gas into the processing container;
an electrode provided to face the stage; and
a power applicator configured to apply, to the electrode, a first power with a first frequency higher than 300 MHz and a second power with a second frequency lower than the first frequency in a superimposition manner such that the processing gas inside the processing container is plasmarized to form a silicon nitride film on the substrate.
